(19) United States
(12) Patent Application Publication
(10) Pub. No.: US 2026/0287536 A1
(43) Pub. Date: Sep. 24, 2026

(54) MEASURING METHOD AND MEASURING SYSTEM

(71) Applicant: HIOKI E.E. CORPORATION, Nagano (JP)

(72) Inventors: Hideo MATSUBAYASHI, Nagano (JP); Mikio YAMASHITA, Nagano (JP)

(21) Appl. No.: 19/476,011

(22) PCT Filed: Apr. 19, 2024
(86) PCT No.: PCT/JP2024/015573

§ 371 Date: Oct. 16, 2025

(30) Foreign Application Priority Data
Apr. 21, 2023 (JP) 2023-070158

(51) Int. Cl. G01N 27/04; G01N 27/20; G01R 27/14

(52) U.S. Cl. CPC G01N 27/045; G01N 27/041; G01N 27/20; G01R 27/14

(57) ABSTRACT

A measuring method includes adjusting contact positions of first and second contactors, and adjusting contact positions of third and fourth contactors so that an interval between the third and fourth contactors is larger than an interval between the first and second contactors. The measuring method also includes supplying a constant current between the third and fourth contactors and detecting a voltage between the first and second contactors. At this time, the first contactor contacts the weld workpiece, the second contactor contacts the weld piece, the third contactor contacts the weld workpiece so as to be separated from the weld zone than the first contactor, and the fourth contactor contacts the weld piece or another weld workpiece so as to be separated from the weld zone than the second contactor.

### CROSS REFERENCE TO RELATED APPLICATIONS

This application is a U.S. national stage filing of PCT/JP2024/015573, filed Apr. 19, 2024, which international application claims the benefit of and priority to Japanese Application No. 2023-070158, filed Apr. 21, 2023, the entire contents of these applications are incorporated herein by reference.

### TECHNICAL FIELD

The present invention relates to a measuring method and a measuring system for measuring the state of a weld zone.

### BACKGROUND ART

JP2019-60769A discloses an apparatus that measures a resistance value of a weld zone of a secondary battery using a pair of first probes connected to a voltmeter and a pair of second probes connected to an ammeter, the weld zone being configured such that a conductive member is welded to a group of tabs.

The above-described apparatus detects a voltage drop occurring in the weld zone by the voltmeter by bringing one of the first probes and one of the second probes into contact with a first measurement target portion and bringing the other of the first probes and the other of the second probes into contact with a second measurement target portion.

### SUMMARY OF INVENTION

In the above-described measuring method, a potential gradient becomes steep in the vicinity of each of the second probes. For this reason, in the arrangement in which one of the first probes and one of the second probes are brought close to each other and the other of the first probes and the other of the second probes are brought close to each other, there is a problem that a change in voltage occurring between the pair of first probes is increased due to a deviation of a contact position of the first probe.

The present invention has been made in view of such problems, and an object thereof is to curb a decrease in the accuracy of detecting a voltage drop occurring in a weld zone.

### Solution to Problem

According to one aspect of the present invention, a measuring method is executed by one or a plurality of processors to measure a state of a weld zone formed when a weld piece is welded to a weld workpiece. The measuring method includes a first adjustment step of adjusting contact positions of first and second contactors, and a second adjustment step of adjusting contact positions of third and fourth contactors so that an interval between the third contactor and the fourth contactor is larger than an interval between the first contactor and the second contactor. The measuring method further includes a supply step of supplying a constant current between the third contactor and the fourth contactor, and a detection step of detecting a voltage between the first contactor and the second contactor. In the first adjustment step, the first contactor contacts the weld workpiece, and the second contactor contacts the weld piece, and in the second adjustment step, the third contactor contacts the weld workpiece so as to be separated from the weld zone more than the first contactor is, and the fourth contactor contacts the weld workpiece so as to be separated from the weld zone more than the second contactor is or contacts another weld workpiece welded to the weld piece so as to be separated from the weld workpiece.

According to another aspect of the present invention, a measuring method is executed by one or a plurality of processors to measure a state of a weld zone formed when a weld piece is welded to a weld workpiece. The measuring method includes a first adjustment step of adjusting contact positions of third and fourth contactors, and a second adjustment step of adjusting contact positions of first and second contactors so that an interval between the first and second contactors is smaller than an interval between the third and fourth contactors. The measuring method further includes a supply step of supplying a constant current between the third contactor and the fourth contactor, and a detection step of detecting a voltage between the first contactor and the second contactor. In the first adjustment step, the third contactor contacts the weld workpiece, and the fourth contactor contacts the weld piece or contacts another weld workpiece welded to the weld piece so as to be separated from the weld workpiece, and in the second adjustment step, the first contactor contacts the weld workpiece so as to be closer to the weld zone than the third contactor is, and the second contactor contacts the weld zone so as to be closer to the weld zone than the fourth contactor is.

According to these aspects, the third contactor for supplying a constant current is spaced apart from the first contactor for detecting a voltage by a predetermined interval, and similarly, the fourth contactor is spaced apart from the second contactor by a predetermined interval. Thereby, there is less likely to be an effect due to a steep potential gradient occurring in the vicinity of the third and fourth contactors, and thus it is possible to curb a decrease in the detection accuracy of a voltage drop occurring in the weld zone.

### BRIEF DESCRIPTION OF DRAWINGS

FIG. 1 is a diagram illustrating the configuration of a measuring system according to a first embodiment.

FIG. 2A is a diagram illustrating an example of potential distributions of a measured object in a good welded state.

FIG. 2B is a diagram illustrating an example of potential distributions of a measured object in a poor weld state.

FIG. 3A is a diagram illustrating a relationship between contact positions of four probes.

FIG. 3B is a diagram illustrating another example showing a relationship between contact positions of four probes.

FIG. 4 is a flowchart showing a measuring method according to the first embodiment.

FIG. 5 is a diagram illustrating a relationship between contact positions of four probes according to a second embodiment.

FIG. 6 is a diagram illustrating a relationship between contact positions of four probes according to a third embodiment.

FIG. 7A is a diagram illustrating an example of potential distributions of a measured object in a good welded state.

FIG. 7B is a diagram illustrating an example of potential distributions of a measured object in a poor weld state.

### DESCRIPTION OF EMBODIMENTS

Embodiments of the present invention will be described below with reference to the accompanying drawings. In the present description, identical elements are given identical reference signs throughout.

### First Embodiment

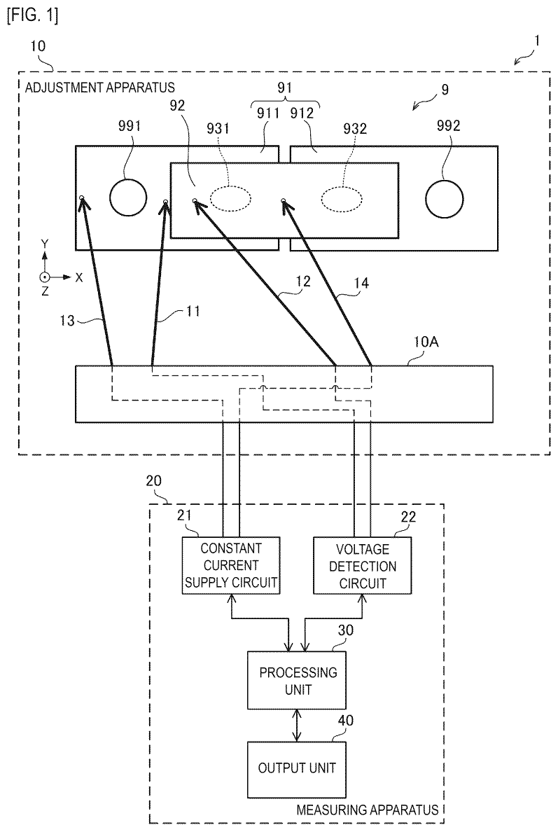

FIG. 1 is a block diagram illustrating the configuration of a measuring system according to a first embodiment.

A measuring system 1 is a system for measuring the state of one or a plurality of weld zones formed on a measured object 9 using a four-terminal method. The measuring system 1 includes a computer configured with one or a plurality of processors, and a computer-readable recording medium. The recording medium stores a program for implementing functions in the first embodiment.

The measured object 9 is a bonded body in which a weld piece 92 is welded to a weld workpiece 91 at one or a plurality of locations. The weld piece 92 is welded to the weld workpiece 91 by, for example, laser welding.

In the first embodiment, the weld workpiece 91 is configured with a weld workpiece 911 and a weld workpiece 912 that are separated from each other, and the measured object 9 is a bonded body obtained by welding one side of the weld piece 92 to the weld workpiece 911 and welding the other side of the weld piece 92 to the weld workpiece 912.

The measured object 9 is an electrode component of a secondary battery including a large number of single cells, the weld workpieces 911 and 912 are electrodes of the single cells configuring the secondary battery, and the weld piece 92 is a member connecting the electrodes of the single cells configuring the secondary battery, that is, a so-called bus bar.

The measured object 9 includes one or a plurality of weld zones formed when the weld piece 92 is welded to the weld workpiece 91. In FIG. 1, for convenience, a region of a weld zone formed on a contact surface between the weld workpiece 91 and the weld piece 92 is indicated by a broken line.

In the measured object 9 of the first embodiment, a weld zone 931 is formed in the middle of a contact surface between the weld workpiece 911 and the weld piece 92, and a weld zone 932 is formed in the middle of a contact surface between the weld workpiece 912 and the weld piece 92. In addition, holes 991 and 992 are formed in exposed surfaces of the weld workpieces 911 and 912 other than the contact surfaces.

The measuring system 1 of the first embodiment includes an adjustment apparatus 10 and a measuring apparatus 20. The measuring apparatus 20 includes a constant current supply circuit 21, a voltage detection circuit 22, a processor 30, and an output circuit 40.

The adjustment apparatus 10 is an apparatus for adjusting a positional relationship between the measured object 9 and four probes 11 to 14. The adjustment apparatus 10 adjusts contact positions of the respective probes 11 to 14 by driving one or both of the group of the probes 11 to 14 and the measured object 9.

The adjustment apparatus 10 of the first embodiment includes four probes 11 to 14 and a driving circuit 10A, and carries the measured object 9 into its housing and fixes the measured object 9 at a predetermined position. Hereinafter, the longitudinal direction and the lateral direction of the measured object 9 are defined as an X-axis direction and a Y-axis direction, respectively, and the thickness direction of the measured object 9 is defined as a Z-axis direction.

The driving circuit 10A separately drives the four probes 11 to 14 in the directions of three axes, that is, an X-axis, a Y-axis, and a Z-axis, which are orthogonal to one another. The driving circuit 10A has, for example, functions of correcting a probe position in a plane formed by the X-axis and the Y-axis and correcting the height of the probe.

The pair of probes 11 and 12 are detection probes electrically connected to a positive electrode terminal and a negative electrode terminal of the voltage detection circuit 22, respectively. The probe 11 is equivalent to a first contactor for detecting a voltage in the four-terminal method, and the probe 12 is equivalent to a second contactor for detecting a voltage in the four-terminal method. For example, the pair of probes 11 and 12 are disposed in the vicinity of the weld zone 931 or 932.

The pair of probes 13 and 14 are supply probes electrically connected to a positive electrode terminal and a negative electrode terminal of the constant current supply circuit 21, respectively. The probe 13 is equivalent to a third contactor for supplying a constant current in the four-terminal method, and the probe 14 is equivalent to a fourth contactor for supplying a constant current in the four-terminal method.

The probe 13 is disposed farther away from the weld zone 931 than the probe 11. The probe 14 is disposed farther away from the weld zone 931 than the probe 12. In other words, the probe 11 is disposed closer to the weld zone 931 than the probe 13. The probe 12 is disposed closer to the weld zone 931 than the probe 14. In addition, the pair of probes 13 and 14 may be disposed to sandwich the weld zone 931 or 932.

The measuring apparatus 20 is an apparatus for measuring the state of a weld zone formed on the measured object 9 using the four-terminal method. The measuring apparatus 20 of the first embodiment measures, for example, the magnitude of a voltage, the magnitude of a resistance, and a welded state as the states of the weld zones 931 and 932. The welded state mentioned here means the adhesion between the weld workpiece 91 and the weld piece 92.

As a specific example, the measuring apparatus 20 supplies a constant current to the measured object 9 via the pair of probes 13 and 14, and detects a voltage drop occurring between the pair of probes 11 and 12 in a state where the constant current is supplied.

The measuring apparatus 20 calculates a resistance value between the pair of probes 11 and 12 on the basis of a detected amount of a voltage generated due to a voltage drop between the pair of probes 11 and 12 and a current value of a constant current supplied to the pair of probes 13 and 14.

The constant current supply circuit 21 is a supply circuit that supplies a constant current between the pair of probes 13 and 14. The magnitude of the constant current supplied by the constant current supply circuit 21 is, for example, several [A], and is set to 1.0 [A] in the first embodiment. The constant current supply circuit 21 outputs the value of the constant current supplied to the pair of probes 13 and 14 to the processor 30.

The voltage detection circuit 22 is a detection circuit that detects a voltage between the pair of probes 11 and 12. The magnitude of the voltage detected by the voltage detection circuit 22 is, for example, several [μV]. The voltage detection circuit 22 outputs the amount of the detected voltage to the processor 30.

The processor 30 is configured with one or a plurality of processors. Examples of the processor include a central processing unit (CPU) and a micro processor unit (MPU).

The processor 30 determines the welded state of the weld zones 931 and 932 using the amount of voltage detected by the voltage detection circuit 22. For example, the processor 30 determines that the welded state is poor when the amount of the detected voltage exceeds a predetermined reference value. The predetermined reference value mentioned herein is determined in advance by a result of an experiment, a simulation, or the like performed using the measured object 9 in a good welded state.

Alternatively, the processor 30 calculates the resistance values of the weld zones 931 and 932 by dividing the amount of voltage detected by the voltage detection circuit 22 by the current value of the constant current supplied by the constant current supply circuit 21. The processor 30 may determine the welded state of the weld zones 931 and 932 using the calculated resistance value.

The output circuit 40 outputs the measurement information acquired from the processor 30. Examples of the measurement information include a voltage generated in the weld zones 931 and 932, values of a constant current and a resistance, a determination result indicating whether the welded state is good or poor, and the like. The output circuit 40 displays the acquired measurement information, stores the measurement information in an internal or external memory, or transmits the measurement information to an external device.

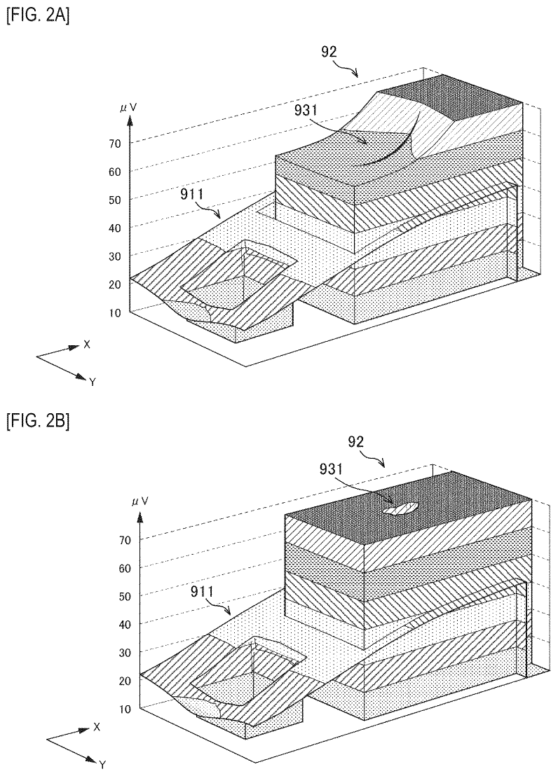

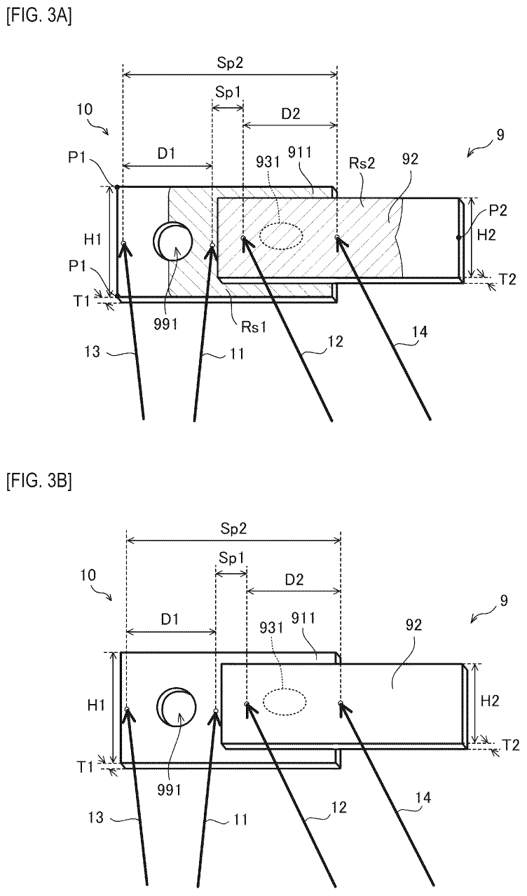

Next, a positional relationship between contact portions of the probes 11 to 14 with respect to the measured object 9 will be described with reference to FIGS. 2A, 2B, 3A, and 3B.

FIGS. 2A and 2B are diagrams illustrating examples of potential distributions generated in the weld workpiece 911 and the weld piece 92 in contact with the weld workpiece 911 in a state where a constant current is supplied from the probe 14 to the probe 13 (in a direction opposite to an arrow of the X-axis) to the weld zone 931 formed by laser welding. In this example, the hole 991 of the weld workpiece 911 is formed in a rectangular shape.

FIG. 2A illustrates a potential distribution when the welded state of the weld zone 931 is good, and FIG. 2B illustrates a potential distribution when the welded state of the weld zone 932 is poor. Here, the higher a potential, the larger a resistance value, which means that adhesion between the weld workpiece 911 and the weld piece 92 is low.

In the weld piece 92 illustrated in FIG. 2A, a current flows from the weld piece 92 to the weld workpiece 911 through the weld zone 931, and thus a potential generated in the weld zone 931 is particularly decreased, and a potential is also decreased in the vicinity of the weld zone 931. As a whole, the potential gently decreases in a direction opposite to the arrow of the X-axis, that is, in a direction in which a supplied current flows.

On the other hand, in the weld piece 92 illustrated in FIG. 2B, a potential is extremely decreased in the weld zone 931, but a potential is not decreased in other regions including the vicinity of the weld zone 931.

For this reason, in order to accurately determine the welded state of the weld zone 931, it is preferable to bring the probe 12 into contact with a region of the surface of the weld piece 92 where a potential is relatively low, as illustrated in FIG. 2A. Specifically, it is preferable to dispose the probe 12 in the weld zone 931 itself, in the vicinity of the weld zone 931, and in a region of the surface of the weld piece 92 closer to the probe 13 than the weld zone 931 on the surface of the weld piece 92.

FIGS. 3A and 3B are diagrams illustrating contact positions of the four probes 11 to 14. In FIGS. 3A and 3B, the weld workpiece 912 is omitted for convenience.

The pair of probes 13 and 14 are disposed such that a current flows through the weld zone 931. The contact positions of the probe 13 and the probe 14 are adjusted such that an interval Sp2 between the probe 13 and the probe 14 is larger than an interval Sp1 between the probe 11 and the probe 12. The probe 13 contacts the weld workpiece 911, and the probe 14 contacts the weld piece 92 in the first embodiment.

It is preferable that the probe 11 contact the weld workpiece 911 at a position within a region Rs1 on the surface of the weld workpiece 911 so that a distance from the weld piece 92 is equal to or less than half a distance to a position P1 farthest from the weld piece 92. Similarly, it is preferable that the probe 12 contact the weld piece 92 at a position within a region Rs2 on the surface of the weld piece 92 so that a distance from the weld workpiece 911 is equal to or less than half a distance to a position P2 farthest from the weld workpiece 911.

It is more preferable that the probe 11 contact the weld workpiece 911 at a position as close as possible to the weld piece 92 on the surface of the weld workpiece 911 so that a distance from the weld piece 92 is equal to or less than one third, one fourth, or the like a distance to the position P1 farthest from the weld piece 92. Similarly, it is more preferable that the probe 12 contact the weld piece 92 at a position as close as possible to the weld workpiece 911 on the surface of the weld piece 92 so that a distance from the weld workpiece 911 is equal to or less than one third, one fourth, or the like a distance to the position P2 farthest from the weld workpiece 911.

For this reason, in the example illustrated in FIGS. 3A and 3B, the probe 11 contacts the weld workpiece 911 closer to the probe 12 than the contact position of the probe 13, and the probe 12 contacts the weld piece 92 closer to the probe 13 than the contact position of the probe 14.

The probe 12 is brought into contact with, for example, a region of the weld zone 931, the vicinity of the weld zone 931, or a region of the surface of the weld piece 92 closer to the probe 13 than the weld zone 931, as described above. In the first embodiment, as illustrated in FIGS. 3A and 3B, the probe 11 is disposed in the vicinity of the probe 12 on the surface of the weld workpiece 911, and the probe 12 is disposed on the probe 13 side with respect to the weld zone 931 on the surface of the weld piece 92.

Subsequently, the contact positions of the pair of probes 13 and 14 will be described in detail.

A potential gradient is steep in the vicinity of the contact position of each of the probe 13 and the probe 14, and when the probe 11 and the probe 12 are brought into contact with the vicinity of the contact positions of the probe 13 and the probe 14, the amount of the detected voltage is greatly changed due to a slight deviation of the contact positions of the probe 11 and the probe 12. As a result, an erroneous determination is likely to occur regarding the welded state of the weld zone 931.

As a countermeasure against this, in the first embodiment, the contact positions of the probe 13 and the probe 14 are adjusted by the adjustment apparatus 10 so that the probe 13 is separated from the probe 11 and the probe 14 is separated from the probe 12.

For example, it is preferable that a distance D1 between the probe 11 and the probe 13 be three times or more a length H1 of the weld workpiece 911 in a direction intersecting an imaginary straight line connecting the probe 13 and the probe 14.

When it is difficult to secure the length H1 of the weld workpiece 911 being three times or more, it is preferable that the distance D1 between the probe 13 and the probe 11 be adjusted to a distance closest to a distance that is three times the length H1 of the weld workpiece 911.

It is preferable that the distance D1 between the probe 11 and the probe 13 be three times or more a thickness T1 of the weld workpiece 911. When it is difficult to secure the thickness T1 of the weld workpiece 911 three times or more, it is preferable that the distance D1 between the probes 11 and 13 be adjusted to a distance closest to a distance that is three times the thickness T1 of the weld workpiece 911.

Similarly, it is preferable that a distance D2 between the probes 12 and 14 be adjusted to a distance three times or more or closest to three times the length H2 of the weld workpiece 911, or three times or more or closest to three times the thickness T2 of the weld piece 92.

In the above description, an example has been described in which the contact positions of the pair of probes 13 and 14 are determined relative to the contact positions of the pair of probes 11 and 12, but the contact positions of the pair of probes 11 and 12 may also be determined relative to the contact positions of the pair of probes 13 and 14. The contact positions of the pair of probes 11 and 12 may be adjusted such that the interval Sp1 between the probe 11 and the probe 12 is smaller than the interval Sp2 between the probe 13 and the probe 14.

Further, regarding the contact position of the probe 14, the probe 14 may be disposed not to contact the surface of the weld piece 92 but to contact another surface of the weld workpiece 912 welded to the weld piece 92 so as to be separated from the weld workpiece 911.

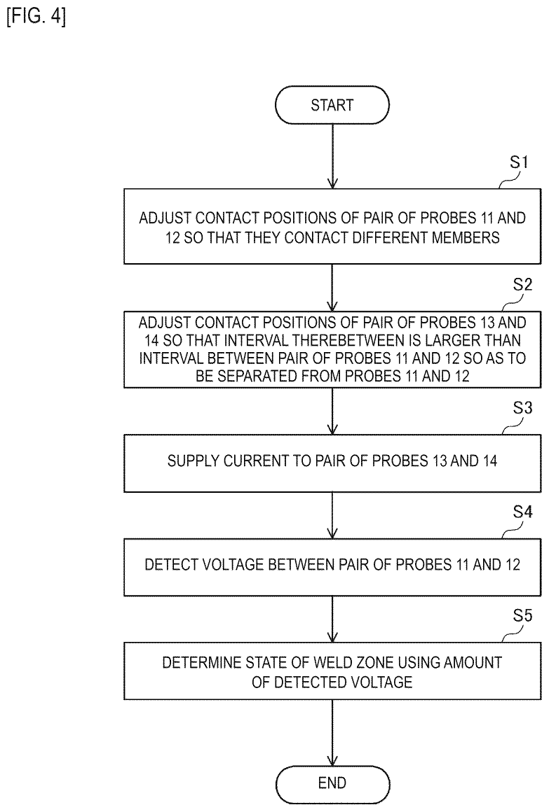

Next, the operation of the measuring system 1 will be described with reference to FIG. 4.

FIG. 4 is a flowchart showing a processing procedure of a measuring method in the first embodiment.

In step S1, the measuring system 1 adjusts each contact position so that the probe 11 contacts the weld workpiece 911 and the probe 12 contacts the weld piece 92.

In step S2, the measuring system 1 adjusts the contact positions of the probe 13 and the probe 14 so that the interval Sp2 between the probe 13 and the probe 14 is larger than the interval Sp1 between the probe 11 and the probe 12. At this time, the probe 13 is separated from the probe 11, and the probe 14 is separated from the probe 12.

For example, the probe 11 contacts the weld workpiece 911 at a position on the surface of the weld workpiece 911 so that a distance from the weld piece 92 is equal to or less than half a distance to a position farthest from the weld piece 92. In addition, the probe 12 contacts the weld piece 92 at a position on the surface of the weld piece 92 so that a distance from the weld workpiece 911 is equal to or less than half a distance to a position farthest from the weld workpiece 911.

In step S3, the measuring system 1 supplies a constant current between the probe 13 and the probe 14.

In step S4, the measuring system 1 detects a voltage generated between the probe 11 and the probe 12.

In step S5, the measuring system 1 determines the state of the weld zone 931 using the detected amount of the detected voltage. Examples of the state of the weld zone 931 include the magnitude of a resistance, a welded state indicating adhesion between the weld workpiece 911 and the weld piece 92, and the like.

For example, the measuring system 1 compares the amount of the voltage detected in step S5 with a reference value to determine whether the weld zone 931 is in a good or poor state. The reference value mentioned here is determined by a result of an experiment, a simulation, or the like using a measured object 9 which is a non-defective object in a good welded state, and is determined in advance using, for example, the detected amount of the measured object 9 which is the non-defective object as a reference value.

Alternatively, the measuring system 1 may calculate a resistance value on the basis of the value of the constant current supplied in step S4 and the value of the voltage detected in step S5, and compare the resistance value with a predetermined reference value to determine whether the weld zone 931 is in a good or poor state.

When the process of step S5 is completed, the series of processes for the measuring method in the first embodiment ends.

Next, operations and effects of the first embodiment will be described.

The measuring method of the first embodiment is a method that is executed by one or a plurality of processors configuring the measuring system 1 to measure the state of the weld zone 931 formed when the weld piece 92 is welded to the weld workpiece 91.

The measuring method includes step S1 as a first adjustment step, step S2 as a second adjustment step, step S3 as a supply step, and step S4 as a detection step.

In step S1, the contact positions of the probe 11 and the probe 12 are adjusted, and in step S2, the contact positions of the probe 13 and the probe 14 are adjusted such that the interval Sp2 between the probe 13 and the probe 14 is larger than the interval Sp1 between the probe 11 and the probe 12. In step S3, a constant current is supplied between the probe 13 and the probe 14, and in step S4, a voltage between the probe 11 and the probe 12 is detected.

In step S1, the probe 11 contacts the weld workpiece 911, and the probe 12 contacts the weld piece 92. Then, in step S2, the probe 13 contacts the weld workpiece 911 at a position more distant from the weld zone 931 than the probe 11, and the probe 14 contacts the weld piece 92 at a position more distant from the weld zone 931 than the probe 12.

Similarly, the measuring system 1 of the first embodiment is a system that measures the state of the weld zone 931 formed when the weld piece 92 is welded to the weld workpiece 91. The measuring system 1 includes the adjustment apparatus 10 that adjusts the contact positions of the probe 11 and the probe 12 and adjusts the contact positions of the probe 13 and the probe 14 so that the interval Sp2 between the probe 13 and the probe 14 is larger than the interval Sp1 between the probe 11 and the probe 12.

The measuring system 1 further includes the constant current supply circuit 21 that supplies a constant current between the probe 13 and the probe 14, and the voltage detection circuit 22 that detects a voltage between the probe 11 and the probe 12.

The adjustment apparatus 10 brings the probe 11 into contact with the weld workpiece 91 and brings the probe 12 into contact with the weld piece 92. At this time, the adjustment apparatus 10 brings the probe 13 into contact with the weld workpiece 911 by separating the probe 13 from the weld zone 931 more than the probe 11, and brings the probe 14 into contact with the weld piece 92 by separating the probe 14 from the weld zone 931 more than the probe 12.

Alternatively, in step S2, the contact positions of the probe 11 and the probe 12 may be adjusted such that the interval Sp1 between the probe 11 and the probe 12 is smaller than the interval Sp2 between the probe 13 and the probe 14. In this case, in step S1, the probe 13 contacts the weld workpiece 911, and the probe 14 contacts the weld piece 92. Then, in step S2, the probe 11 is brought closer to the weld zone 931 than the probe 13 and brought into contact with the weld workpiece 911, and the probe 12 is brought closer to the weld zone 931 than the probe 14 and brought into contact with the weld piece 92.

Similarly, the adjustment apparatus 10 of the measuring system 1 may adjust the contact positions of the probe 11 and the probe 12 so that the interval Sp1 between the probe 11 and the probe 12 is smaller than the interval Sp2 between the probe 13 and the probe 14. In this case, the adjustment apparatus 10 brings the probe 13 into contact with the weld workpiece 911 and brings the probe 14 into contact with the weld piece 92. The adjustment apparatus 10 brings the probe 11 closer to the weld zone 931 than the probe 13 and brings the probe 11 into contact with the weld workpiece 911, and brings the probe 12 closer to the weld zone 931 than the probe 14 and brings the probe 12 into contact with the weld piece 92.

According to the above-described measuring method and the configuration of the measuring system 1, the probe 13 for supplying a constant current is spaced apart from the probe 11 for detecting a voltage by a predetermined interval, and similarly, the probe 14 is spaced apart from the probe 12 by a predetermined interval. Thereby, this makes it difficult to be affected by a steep potential gradient generated in the vicinity of each of the probe 13 and the probe 14, and thus it is possible to curb a decrease in the detection accuracy of a voltage drop occurring in the weld zone 931.

Further, in the first embodiment, the probe 11 contacts the weld workpiece 911 at a position (Rs1) on the surface of the weld workpiece 911 so that a distance from the weld piece 92 is equal to or less than half a distance to a position P1 farthest from the weld piece 92.

According to this configuration, the probe 11 is easily disposed in a region where a potential gradient is gentler than a steep potential gradient occurring in the vicinity of the probe 13 and which is easily affected by the welded state of the weld zone 931.

In the first embodiment, the probe 12 contacts the weld piece 92 at a position (Rs2) on the surface of the weld piece 92 a distance from the weld workpiece 911 is equal to or less than half a distance to the position P2 farthest from the weld workpiece 911.

According to this configuration, the probe 12 is easily disposed in a region where a potential gradient is gentler than a steep potential gradient occurring in the vicinity of the probe 14 and which is easily affected by the welded state of the weld zone 931.

In the first embodiment, when the weld workpiece 911 and the weld piece 92 are plate-shaped, it is preferable that the distance D1 between the probe 11 and the probe 13 be adjusted to a distance that is three times or more or closest to three times the length H1 of the weld workpiece 911 in a direction intersecting an imaginary straight line connecting the probe 12 and the probe 14. Alternatively, it is preferable that the distance D1 between the probe 11 and the probe 13 be adjusted to a distance that is three times or more or closest to three times the thickness T1 of the weld workpiece 911.

According to this configuration, the probe 11 is easily disposed in a region where a potential gradient is gentler than a steep potential gradient occurring in the vicinity of the probe 13. Thus, even when the contact position of the probe 11 is slightly shifted due to the adjustment accuracy of the adjustment apparatus 10, it is possible to reduce a significant increase or decrease in the amount of a detected voltage between the probe 11 and the probe 12 due to the shift. Thus, it is possible to curb a decrease in the detection accuracy of a voltage drop occurring in the weld zone 931.

Further, in the first embodiment, when the weld workpiece 911 and the weld piece 92 are plate-shaped, it is preferable that the distance D2 between the probe 12 and the probe 14 be adjusted to a distance that is three times or more or closest to three times the length H2 of the weld piece 92 in a direction intersecting an imaginary straight line connecting the probe 13 and the probe 14. Alternatively, it is preferable that the distance D2 between the probes 12 and 14 be adjusted to a distance that is three times or more or closest to three times the thickness T2 of the weld piece 92.

According to this configuration, the probe 12 is easily disposed in a region where a potential gradient is gentler than a steep potential gradient occurring in the vicinity of the probe 14. Thus, even when the contact position of the probe 12 is slightly shifted due to the adjustment accuracy of the adjustment apparatus 10, it is possible to reduce a significant increase or decrease in the amount of a detected voltage between the probe 11 and the probe 12 due to the shift. Thus, it is possible to curb a decrease in the detection accuracy of a voltage drop occurring in the weld zone 931.

Further, in step S1 in the first embodiment, the probe 12 contacts the weld zone 931 itself on the surface of the weld piece 92, the vicinity of the weld zone 931, or a region closer to the probe 13 side than the weld zone 931, as illustrated in FIG. 1. That is, the contact position of the probe 12 is disposed in a potential decrease region where a potential is relatively low in the weld piece 92 illustrated in FIG. 2A.

According to this configuration, when the welded state between the weld workpiece 911 and the weld piece 92 is poor, the potential of the probe 11 increases greatly as compared with when the probe 11 is brought into contact with a region other than the potential decrease region, as illustrated in FIG. 2B. Thus, a voltage between the probe 11 and the probe 12 rises, and thus the state of the weld zone 931 can be accurately determined to be poor.

### Second Embodiment

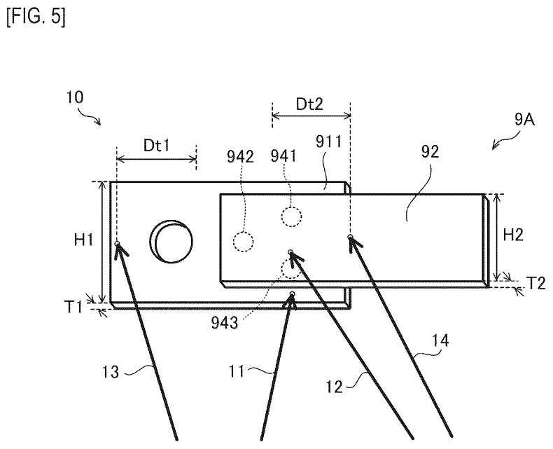

Next, a measuring system 1 according to a second embodiment will be described with reference to FIG. 5. The second embodiment is different from the first embodiment in that a plurality of weld zones are formed in a measured object. Since the other configurations are the same as or equivalent to those of the measuring system 1 of the first embodiment, these configurations will be described with the same reference numerals as those in the first embodiment.

FIG. 5 is a diagram illustrating contact positions of probes 11 to 14 in the second embodiment. Three weld zones 941 to 943 are formed in a measured object 9A of the second embodiment.

The weld zone 941 is present in a region on one side (closer side) in an intersecting direction intersecting a direction in which a weld workpiece 911 and a weld piece 92 are connected to each other on the surface of the weld piece 92. In addition, the weld zone 942 is present in a region of the surface of the weld piece 92 between the weld zone 941 and the weld zone 943 in the intersecting direction, and the weld zone 943 is present in a region of the surface of the weld piece 92 on the other side (closer side) in the intersecting direction.

The measuring system 1 of the second embodiment detects a voltage between the pair of probes 11 and 12 for each of the weld zones 941 to 943.

The contact positions of the pair of probes 13 and 14 in the second embodiment are the same as the contact positions in the first embodiment, and are fixed at the same position for each weld zone by an adjustment apparatus 10.

On the other hand, the contact positions of the pair of probes 11 and 12 are moved to different positions by the adjustment apparatus 10 so as to sandwich a weld zone to be detected for each of the weld zones 941 to 943.

For example, as illustrated in FIG. 5, the pair of probes 13 and 14 are disposed to sandwich the weld zone 943, on a side closer to the weld zone 943 to be detected than the other weld zones 941 and 942, with respect to the weld zone 943 to be detected.

In this manner, the pair of probes 13 and 14 are disposed for each weld zone to be detected so as to sandwich the weld zone to be detected on a side closer to the weld zone to be detected than the other weld zones.

In this state, it is preferable that the pair of probes 11 and 12 be disposed such that a distance between the pair of probes 11 and 12 is the shortest. As described above, it is preferable that the probe 11 be disposed on the weld workpiece 911 at a position on the surface of the weld workpiece 911 so that a distance from the weld piece 92 is equal to or less than half a distance to a position farthest from the weld piece 92. Similarly, it is preferable that the probe 12 be disposed on the weld piece 92 at a position on the surface of the weld piece 92 so that a distance from the weld workpiece 91 is equal to or less than half a distance to a position farthest from the weld workpiece 911.

Further, it is more preferable that the probe 11 contact the weld workpiece 911 at a position as close as possible to the weld piece 92 on the surface of the weld workpiece 911 so that a distance from the weld piece 92 is equal to or less than one third, one fourth, or the like a distance to a position farthest from the weld piece 92. Similarly, it is more preferable that the probe 12 contact the weld piece 92 at a position as close as possible to the weld workpiece 911 on the surface of the weld piece 92 so that a distance from the weld workpiece 911 is equal to or less than one third, one fourth, or the like a distance to a position farthest from the weld workpiece 911.

In the second embodiment, an example in which the contact positions of the pair of probes 13 and 14 are fixed has been described, but the adjustment apparatus 10 may move the contact positions of the pair of probes 13 and 14 for each weld zone.

For example, for each of the weld zones, the adjustment apparatus 10 may adjust the contact position of the probe 13 so that a distance between the probe 11 and the probe 13 is three times or more the thickness T1 of the weld workpiece 911 or closest to a distance Dt1 that is three times the thickness T1 of the weld workpiece 911. Similarly, the adjustment apparatus 10 may adjust, for each weld zone, the contact position of the probe 14 so that a distance between the probe 12 and the probe 14 is three times or more the thickness T2 of the weld piece 92 or closest to a distance Dt2 that is three times the thickness T2 of the weld piece 92.

Alternatively, the adjustment apparatus 10 may adjust, for each weld zone, the contact position of the probe 11 so that a distance between the probe 11 and the probe 13 is three times or more or closest to three times a length H1 of the weld workpiece 911. Similarly, the contact position of the probe 12 may be adjusted such that a distance between the probe 12 and the probe 14 is three times or more or closest to three times a length H2 of the weld piece 92.

Next, operation and effects of the second embodiment will be described.

In the second embodiment, a plurality of weld zones 941 to 943 are formed in the weld workpiece 911 and the weld piece 92, the probe 11 and the probe 12 are moved to different positions for each weld zone, and the probe 13 and the probe 14 are fixed to the same position for each weld zone.

According to this configuration, the probe 11 and the probe 12 move to different positions so as to sandwich a detection target for each weld zone, and thus it is possible to accurately determine the welded state of each of the weld zones 941 to 943 compared to when the probes are fixed to the same contact position for each weld zone.

In addition, the contact position of the probe 13 is fixed at a position adjusted to be separated from the probe 11 even in the control content in which the probe 11 moves for each weld zone. Similarly, the contact position of the probe 14 is fixed at a position adjusted to be separated from the probe 12 even in the control content in which the probe 12 moves for each weld zone.

Thereby, it is possible to reduce the amount of driving of the probe 13 and the probe 14 by the adjustment apparatus 10 while avoiding contacts of the probe 11 and the probe 12 with the vicinity of the probe 13 and the probe 14 having a steep potential gradient. Thus, it is possible to reduce the load of the adjustment apparatus 10 while curbing a decrease in detection accuracy.

Further, in the second embodiment, the probe 11 and the probe 12 are disposed for each weld zone to be detected, for example, on a side closer to the weld zone 943 to be detected than the other weld zones 941 and 942 so as to sandwich the weld zone 943 to be detected.

According to this configuration, when a voltage between the probe 11 and the probe 12 is detected, it is possible to curb the influence of the welded state of the other weld zones 941 and 942 from being added to a detection result. Thereby, it is possible to improve the detection accuracy of a voltage drop occurring in the weld zone to be detected.

In addition, the probe 11 and the probe 12 may be disposed such that a distance between the probe 11 and the probe 12 is the shortest.

According to this configuration, it is possible to curb the influence of the states of the weld zones 941 and 942 other than the weld zone 943 to be detected on a detection result, and it is possible to improve the detection accuracy.

### Third Embodiment

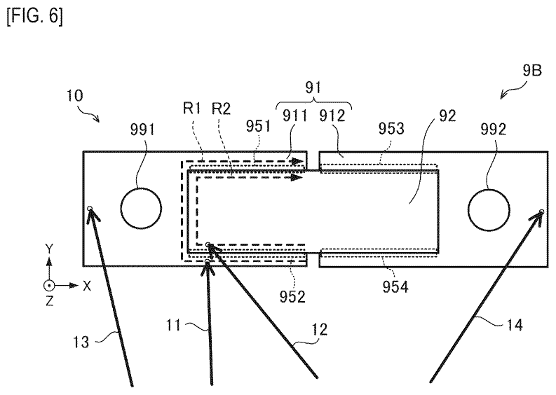

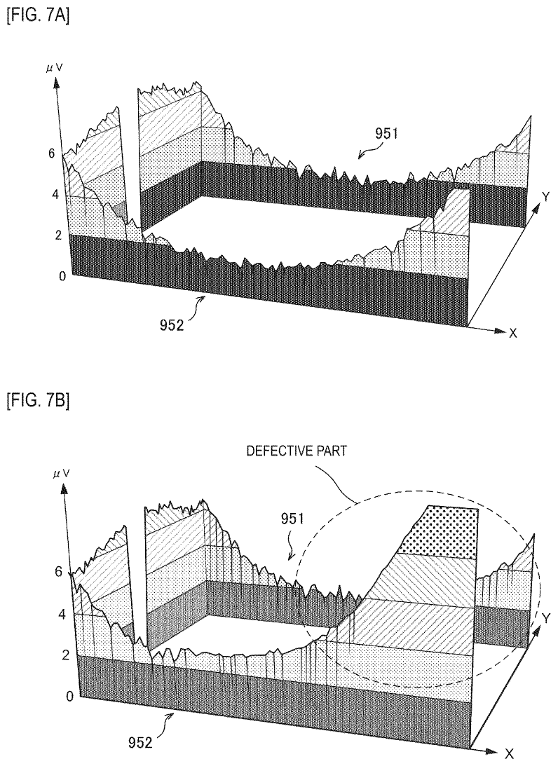

Next, a measuring system 1 according to a third embodiment will be described with reference to FIGS. 6 and 7. The third embodiment is different from the first embodiment in that a linear weld zone is formed in a measured object. Since the other configurations are the same as or equivalent to those of the measuring system 1 of the first embodiment, these configurations will be described with the same reference numerals as those of the first embodiment.

FIG. 6 is a diagram illustrating contact positions of probes 11 to 14 in the third embodiment. Linear weld zones 951 to 954 are formed on a measured object 9B of the third embodiment.

In the measured object 9B, the linear weld zones 951 and 952 are formed along two opposing side surfaces of the weld piece 92 in the vicinity of the side surfaces. Further, the linear weld zones 953 and 954 are formed along two opposing side surfaces of the weld piece 92 in the vicinity of the side surfaces.

Each of the linear weld zones 951 to 954 is a group of weld zones in which a large number of weld zones are continuously formed. In this manner, a plurality of weld zones are formed in the measured object 9B, as in the second embodiment.

The measuring system 1 of the third embodiment detects a voltage between the pair of probes 11 and 12 while sequentially moving the pair of probes 11 and 12 along the linear weld zones 951 to 954.

The contact positions of the pair of probes 13 and 14 are fixed at the same position by the adjustment apparatus 10, as in the second embodiment. In the third embodiment, the probe 13 is disposed in the vicinity of an end surface of a weld workpiece 911 farther from the weld piece 92, and the probe 14 is disposed in the vicinity of an end surface of a weld workpiece 912 farther from the weld piece 92. For this reason, the probe 14 is separated from the weld zones 951 to 954 more than the probe 12, and is brought into contact with not the weld piece 92 but another weld workpiece 912 welded to the weld piece 92 so as to be separated from the weld workpiece 911.

On the other hand, the contact positions of the pair of probes 11 and 12 are moved by the adjustment apparatus 10 to different positions so as to sandwich a linear weld zone to be detected for each of the linear weld zones 951 to 954.

In the third embodiment, the pair of probes 11 and 12 are disposed to sandwich a weld part to be detected among the linear weld zones 951 to 954 in a state of being closer to the weld part to be detected than the other weld parts. For example, the pair of probes 11 and 12 are disposed such that a distance between the pair of probes 11 and 12 is the shortest in the positional relationship.

Further, it is preferable that the probe 11 be disposed on the weld workpiece 911 at a position on the surface of the weld workpiece 911 so that a distance from the weld piece 92 is equal to or less than half a distance to a position farthest from the weld piece 92. Similarly, it is preferable that the probe 12 be disposed on the weld piece 92 as a position on the surface of the weld piece 92 so that a distance from the weld workpiece 911 is equal to or less than half a distance to a position farthest from the weld workpiece 911.

Further, it is more preferable that the probe 11 contact the weld workpiece 911 at a position as close as possible to the weld piece 92 on the surface of the weld workpiece 911 so that a distance from the weld piece 92 is equal to or less than one third, one fourth, or the like a distance to a position farthest from the weld piece 92. Similarly, it is more preferable that the probe 12 contact the weld piece 92 at a position as close as possible to the weld workpiece 911 on the surface of the weld piece 92 so that a distance from the weld workpiece 911 is equal to or less than one third, one fourth, or the like a distance to a position farthest from the weld workpiece 911.

As illustrated in FIG. 6, the adjustment apparatus 10 of the third embodiment sequentially moves the pair of probes 11 and 12 so that an imaginary straight line between the pair of probes 11 and 12 is orthogonal to the linear weld zones 951 and 952 so as to reduce a distance between the pair of probes 11 and 12.

Specifically, the adjustment apparatus 10 moves the contact position of the probe 11 along a path R1 and moves the contact position of the probe 12 along a path R2 so that the pair of probes 11 and 12 sandwich the linear weld zones 951 and 952.

FIGS. 7A and 7B are diagrams illustrating the magnitudes of potentials detected when the probe 11 and the probe 12 are moved on the path R1 and the path R2 illustrated in FIG. 6, respectively. Here, the higher the potential of a weld part, the larger a resistance value and the lower the adhesion.

FIG. 7A illustrates a potential distribution of the measured object 9B in which the welded state of the linear weld zones 951 and 952 is good, and FIG. 7B illustrates a potential distribution of the measured object 9B in which the welded state of only a part of the linear weld zone 952 is poor.

By comparing the potential distribution of the non-defective object illustrated in FIG. 7A with the potential distribution of the defective object illustrated in FIG. 7B, the defective parts of the linear weld zones 951 and 952 can be specified.

Next, operations and effects of the third embodiment will be described.

The adjustment apparatus 10 of the third embodiment adjusts the contact positions of the probe 13 and the probe 14 so that an interval between the probe 13 and the probe 14 is larger than an interval between the probe 11 and the probe 12, as in the first embodiment.

Specifically, the adjustment apparatus 10 brings the probe 13 into contact with the weld workpiece 911 by separating the probe 13 from the weld zones 951 to 954 more than the probe 11, and brings the probe 14 into contact with another weld workpiece 912 welded to the weld piece 92 so as to be separated from the weld workpiece 911 by separating the probe 14 from the weld zones 951 to 954 more than the probe 12. For this reason, the probe 13 is brought into contact with the weld workpiece 911 at a position more distant from the weld zones 951 to 954 than the probe 11, and the probe 14 is brought into contact with the weld workpiece 912 at a position more distant from the weld zones 951 to 954 than the probe 12.

Alternatively, the adjustment apparatus 10 adjusts the contact positions of the probe 11 and the probe 12 so that the interval between the probe 11 and the probe 12 is smaller than the interval between the probe 13 and the probe 14. In this case, the adjustment apparatus 10 brings the probe 13 into contact with the weld workpiece 911 and brings the probe 14 into contact with another weld workpiece 912 welded to the weld piece 92 so as to be separated from the weld workpiece 911.

The adjustment apparatus 10 brings the probe 11 closer to the weld zones 951 to 954 than the probe 13 to bring the probe 11 into contact with the weld workpiece 911, and brings the probe 12 closer to the weld zones 951 to 954 than the probe 14 to bring the probe 12 into contact with the weld piece 92. For this reason, the probe 11 is brought closer to the weld zones 951 to 954 than the probe 13 and brought into contact with the weld workpiece 911, and the probe 12 is brought closer to the weld zones 951 to 954 than the probe 14 and brought into contact with the weld piece 92.

More specifically, the adjustment apparatus 10 fixes the pair of probes 13 and 14 to the linear weld zones 951 to 954 so as to be separated from each other, and causes the pair of probes 11 and 12 to perform scanning along the linear weld zones 951 to 954 so as to face each other.

Thereby, it is possible to easily specify parts in a poor welded state in the linear weld zones 951 to 954 while preventing the pair of probes 11 and 12 from coming into contact with a region where a potential gradient occurring in the vicinity of the pair of probes 13 and 14 is steep. That is, it is possible to accurately specify a part in a poor welded state while curbing a decrease in detection accuracy.

Although embodiments of the present invention have been described above, the embodiments merely illustrate part of application examples of the present invention, and no limitation of the technical scope of the present invention to the specific configurations of the embodiments described above is intended.

For example, the measured object 9 may be obtained by welding the weld piece 92 to only the weld workpiece 911. In this case, the probe 14 may be disposed in the vicinity of an end surface of the surface of the weld piece 92, which is separated from the weld workpiece 911. In addition, the weld piece 92, the weld workpiece 91, and the measured object 9 are not limited to a rectangular plate shape, and may have an elliptical plate shape, a circular plate shape, a polygonal plate shape, a cylindrical shape, a conical shape, a rod shape, a spherical shape, or a distorted shape thereof.

In the above embodiment, both the probes 11 and 13 are brought into contact with the front surface of the weld workpiece 91, but at least one of the probes 11 and 13 may be brought into contact with the back surface of the weld workpiece 91 while maintaining a positional relationship on the plane.

Further, in the measuring system 1 of the first embodiment, the adjustment apparatus 10 may have the function of the measuring apparatus 20, and the measuring apparatus 20 may control the adjustment apparatus 10.

Further, the adjustment apparatus 10 of the first embodiment is configured to fix the measured object 9 and drive the probes 11 to 14, but may be configured to fix the probes 11 to 14 and move the measured object 9, or may be configured to move both the probes 11 to 14 and the measured object 9.

Further, in the measuring system 1 of the first embodiment, the adjustment apparatus 10 may have the function of the measuring apparatus 20, and the measuring apparatus 20 may control the adjustment apparatus 10.

The present application claims priority based on JP 2023-070158 filed on Apr. 21, 2023, in Japan, the entire contents of which are incorporated by reference herein.

### REFERENCE SIGNS LIST

1 Measuring system
10 Adjustment apparatus
11 to 14 Probe (first to fourth contactors)
20 Measuring apparatus
21 Constant current supply circuit (supply circuit)
22 Voltage detection circuit (detection circuit)
S1 to S4 (First adjustment step, second adjustment step, supply step, detection step)

13. A measuring method executed by one or a plurality of processors to measure a state of a weld zone formed when a weld piece is welded to a weld workpiece, the measuring method comprising:
a first adjustment step of adjusting a contact position of a first contactor and a second contactor;
a second adjustment step of adjusting a contact position of a third contactor and a fourth contactor so that an interval between the third contactor and the fourth contactor is larger than an interval between the first contactor and the second contactor;
a supply step of supplying a constant current between the third contactor and the fourth contactor; and
a detection step of detecting a voltage between the first contactor and the second contactor, wherein
in the first adjustment step, the first contactor contacts the weld workpiece, and the second contactor contacts the weld piece,
in the second adjustment step, the third contactor contacts the weld workpiece so as to be separated from the weld zone more than the first contactor is, and the fourth contactor contacts the weld piece so as to be separated from the weld zone more than the second contactor is or contacts another weld workpiece welded to the weld piece so as to be separated from the weld workpiece, and
the first contactor contacts the weld workpiece at a position on a surface of the weld workpiece so that a distance from the weld piece is equal to or less than half a distance to a position farthest from the weld piece, and the second contactor contacts the weld piece at a position on a surface of the weld piece so that a distance from the weld workpiece is equal to or less than half a distance to a position farthest from the weld workpiece.

14. A measuring method executed by one or a plurality of processors to measure a state of a weld zone formed when a weld piece is welded to a weld workpiece, the measuring method comprising:
a first adjustment step of adjusting a contact position of a third contactor and a fourth contactor;
a second adjustment step of adjusting a contact position of a first contactor and a second contactor so that an interval between the first contactor and the second contactor is smaller than an interval between the third contactor and the fourth contactor;
a supply step of supplying a constant current between the third contactor and the fourth contactor; and
a detection step of detecting a voltage between the first contactor and the second contactor, wherein
in the first adjustment step, the third contactor contacts the weld workpiece, and the fourth contactor contacts the weld piece or contacts another weld workpiece welded to the weld piece so as to be separated from the weld workpiece,
in the second adjustment step, the first contactor contacts the weld workpiece so as to be closer to the weld zone than the third contactor is, and the second contactor contacts the weld piece so as to be closer to the weld zone than the fourth contactor is, and
the first contactor contacts the weld workpiece at a position on a surface of the weld workpiece so that a distance from the weld piece is equal to or less than half a distance to a position farthest from the weld piece, and the second contactor contacts the weld piece at a position on a surface of the weld piece so that a distance from the weld workpiece is equal to or less than half a distance to a position farthest from the weld workpiece.

15. The measuring method according to claim 1, wherein the first contactor contacts the weld workpiece at a position on a surface of the weld workpiece so that a distance from the weld piece is equal to or less than ⅓ of a distance to a position farthest from the weld piece, and the second contactor contacts the weld piece at a position on a surface of the weld piece so that a distance from the weld workpiece is equal to or less than ⅓ of a distance to a position farthest from the weld workpiece.

16. The measuring method according to claim 2, wherein the first contactor contacts the weld workpiece at a position on a surface of the weld workpiece so that a distance from the weld piece is equal to or less than ⅓ of a distance to a position farthest from the weld piece, and the second contactor contacts the weld piece at a position on a surface of the weld piece so that a distance from the weld workpiece is equal to or less than ⅓ of a distance to a position farthest from the weld workpiece.

17. The measuring method according to claim 1, wherein in the weld workpiece and the weld piece each having a plate shape, the distance between the first contactor and the third contactor is a distance that is three times or more or closest to three times a length of the weld workpiece in a direction intersecting an imaginary straight line connecting the third contactor and the fourth contactor, or is a distance that is three times or more or closest to three times a thickness of the weld workpiece.

18. The measuring method according to claim 2, wherein in the weld workpiece and the weld piece each having a plate shape, the distance between the first contactor and the third contactor is a distance that is three times or more or closest to three times a length of the weld workpiece in a direction intersecting an imaginary straight line connecting the third contactor and the fourth contactor, or is a distance that is three times or more or closest to three times a thickness of the weld workpiece.

19. The measuring method according to claim 1, wherein in the weld workpiece and the weld piece each having a plate shape, a distance between the second contactor and the fourth contactor is a distance that is three times or more or closest to three times the length of the weld piece in a direction intersecting an imaginary straight line connecting the third contactor and the fourth contactor, or is a distance that is three times or more or closest to three times the thickness of the weld piece.

20. The measuring method according to claim 2, wherein in the weld workpiece and the weld piece each having a plate shape, a distance between the second contactor and the fourth contactor is a distance that is three times or more or closest to three times the length of the weld piece in a direction intersecting an imaginary straight line connecting the third contactor and the fourth contactor, or is a distance that is three times or more or closest to three times the thickness of the weld piece.

21. The measuring method according to claim 1, wherein the second contactor contacts the weld zone, a vicinity of the weld zone, or a side closer to the third contactor with respect to the weld zone.

22. The measuring method according to claim 2, wherein the second contactor contacts the weld zone, a vicinity of the weld zone, or a side closer to the third contactor with respect to the weld zone.

23. The measuring method according to claim 1, wherein
a plurality of the weld zones are formed in the weld workpiece and the weld piece,
the first contactor and the second contactor move to a different position for each of the weld zones, and
the third contactor and the fourth contactor are fixed at a same position for each of the weld zones.

24. The measuring method according to claim 2, wherein
a plurality of the weld zones are formed in the weld workpiece and the weld piece,
the first contactor and the second contactor move to a different position for each of the weld zones, and
the third contactor and the fourth contactor are fixed at a same position for each of the weld zones.

25. The measuring method according to claim 1, wherein
a plurality of the weld zones are formed in the weld workpiece and the weld piece, and
the first contactor and the second contactor are disposed for each of the weld zones so as to sandwich the weld zone on a side closer to the weld zone with respect to the other weld zones.

26. The measuring method according to claim 2, wherein
a plurality of the weld zones are formed in the weld workpiece and the weld piece, and
the first contactor and the second contactor are disposed for each of the weld zones so as to sandwich the weld zone on a side closer to the weld zone with respect to the other weld zones.

27. The measuring method according to claim 13, wherein the first contactor and the second contactor are disposed such that a distance between the first contactor and the second contactor is shortest.

28. The measuring method according to claim 14, wherein the first contactor and the second contactor are disposed such that a distance between the first contactor and the second contactor is shortest.

29. A measuring system that measures a state of a weld zone formed when a weld piece is welded to a weld workpiece, the measuring system comprising:
an adjustment apparatus that adjusts a contact position of a first contactor and a second contactor and adjusts a contact position of a third contactor and a fourth contactor so that an interval between the third contactor and the fourth contactor is larger than an interval between the first contactor and the second contactor;
a supply circuit that supplies a constant current between the third contactor and the fourth contactor; and
a detection circuit that detects a voltage between the first contactor and the second contactor,
wherein the adjustment apparatus is configured to
bring the first contactor into contact with the weld workpiece and bring the second contactor into contact with the weld piece, and
bring the third contactor into contact with the weld workpiece so as to be separated from the weld zone more than the first contactor is, and bring the fourth contactor into contact with the weld piece so as to be separated from the weld zone more than the second contactor is or bring the fourth contactor into contact with another weld workpiece welded to the weld piece so as to be separated from the weld workpiece, and
the first contactor is brought into contact with the weld workpiece at a position on a surface of the weld workpiece so that a distance from the weld piece is equal to or less than half a distance to a position farthest from the weld piece, and the second contactor is brought into contact with the weld piece at a position on a surface of the weld piece so that a distance from the weld workpiece is equal to or less than half a distance to a position farthest from the weld workpiece.

30. A measuring system that measures a state of a weld zone formed when a weld piece is welded to a weld workpiece, the measuring system comprising:
an adjustment apparatus that adjusts a contact position of a third contactor and a fourth contactor and adjusts a contact position of a first contactor and a second contactor so that an interval between the first contactor and the second contactor is smaller than an interval between the third contactor and the fourth contactor;
a supply circuit that supplies a constant current between the third contactor and the fourth contactor; and
a detection circuit that detects a voltage between the first contactor and the second contactor,
wherein the adjustment apparatus is configured to
bring the third contactor into contact with the weld workpiece and bring the fourth contactor into contact with the weld piece or bring the fourth contactor into contact with another weld workpiece welded to the weld piece so as to be separated from the weld workpiece, and
bring the first contactor closer to the weld zone than the third contactor is to bring the first contactor into contact with the weld workpiece, and bring the second contactor closer to the weld zone than the fourth contactor is to bring the second contactor into contact with the weld piece, and
the first contactor is brought into contact with the weld workpiece at a position on a surface of the weld workpiece so that a distance from the weld piece is equal to or less than half a distance to a position farthest from the weld piece, and the second contactor is brought into contact with the weld piece at a position on a surface of the weld piece so that a distance from the weld workpiece is equal to or less than half a distance to a position farthest from the weld workpiece.
